(19) United States
(12) Patent Application Publication
(10) Pub. No.: US 2012/0168201 A1
(43) Pub. Date: Jul. 5, 2012

(54) THIN METAL FILM ELECTRODE AND FABRICATING METHOD THEREOF

(75) Inventors: Young Ah SONG, Suwon (KR); Byoung Jin Chun, Seoul (KR); Dong Hoon Kim, Seongnam (KR); Sung Il Oh, Seoul (KR)

(73) Assignee: SAMSUNG ELECTRO-MECHANICS CO., LTD.

(21) Appl. No.: 13/222,316

(22) Filed: Aug. 31, 2011

(30) Foreign Application Priority Data
Dec. 30, 2010 (KR) 10-2010-0139232

(51) Int. Cl. B05D 5/12; H01L 21/28; H01B 5/14

(52) U.S. Cl. 174/126.4; 427/123; 427/125; 438/610; 257/E21.158

(57) ABSTRACT

There are provided a method of fabricating a thin metal film electrode and a thin metal film electrode fabricated by the same. The method of fabricating a thin metal film electrode according to an embodiment of the present invention includes applying a metal paste including a metal powder and a dispersant to a substrate to form a thin metal film; and subjecting the thin metal film to reduction firing in an atmosphere containing an organic acid and an aqueous solution in a ratio ranging from 10:90 to 90:10.

### CROSS-REFERENCE TO RELATED APPLICATIONS

This application claims the priority of Korean Patent Application No. 10-2010-0139232 filed on Dec. 30, 2010, in the Korean Intellectual Property Office, the disclosure of which is incorporated herein by reference.

### BACKGROUND OF THE INVENTION

1. Field of the Invention

The present invention relates to a thin metal film electrode and a method of fabricating the same and, more particularly, to a thin metal film electrode capable of being prepared at a low firing temperature and having a low resitivity, and a method of fabricating the same.

2. Description of the Related Art

For the fabrication of wirings used in electrical and/or electronic industrial applications, a method of forming conductive coating layers by using a metal paste has been proposed. In this regard, the metal paste is applied to a substrate by an ink-jet process, followed by drying and firing, to form a thin metal film electrode.

In order to form a thin metal film electrode having low resistivity, a high temperature firing process conducted at a temperature of 200° C. or higher is generally required. However, in a case in which the high temperature firing process is executed at 200° C. or higher, a lot of problems including, for example, damage to the shape of the thin metal film electrode, or the like, may be encountered due to thermal stress.

For this reason, a low temperature firing process has been employed. However, in the case of such low temperature firing, a density of the metal of the thin metal film electrode must be increased in order to reduce a resistivity of the thin metal film electrode. As a result, problems such as an increased number of coatings or film formation works have been entailed.

In addition, in order to reduce the resistivity while decreasing the number of required coatings, if a metal paste having an increased concentration is applied to the thin metal film electrode to thereby increase a metal density of the thin metal film electrode, the metal paste may be unstable and is likely to cause secondary coagulation, thereby causing sedimentation or precipitation of metal particles.

Specifically, if a copper (Cu) paste is used to form a thin metal film electrode, the use of Cu paste entails a significant problem in that the Cu paste may be oxidized when it contacts oxygen during thermal treatment at a low temperature.

### SUMMARY OF THE INVENTION

An aspect of the present invention provides a method of fabricating a thin metal film electrode having low resistivity through low temperature firing and, in particular, a method of fabricating a thin metal film electrode having low resistivity by using relatively low-priced copper (Cu) and a thin metal film electrode manufactured by the same.

According to an aspect of the present invention, there is provided a method of fabricating a thin metal film electrode, the method including: applying a metal paste including a metal power, an organic binder and an organic solvent to a substrate to form a thin metal film; and subjecting the prepared thin metal film to reduction firing in an atmosphere containing an organic acid and an aqueous solution in a ratio ranging from 10:90 to 90:10.

The metal powder may be at least one selected from the group consisting of copper (Cu), silver (Ag), gold (Au), platinum (Pt), palladium (Pd), nickel (Ni), tantalum (Ta), indium (In), tin (Sn), zinc (Zn), chromium (Cr), iron (Fe) and cobalt (Co).

The metal powder may contain nano-sized Cu powder particles.

The metal paste may be a copper paste containing copper powder and a content of the copper powder may range from 10 to 90 parts by weight in relation to 100 parts by weight of the copper paste.

The thin metal film may be treated by reduction firing in an atmosphere containing an organic acid and an aqueous solution in a ratio ranging from 50:50 to 80:20.

The thin metal film may be treated by reduction firing in an atmosphere containing an organic acid and an aqueous solution in a ratio ranging from 60:40 to 70:30.

The aqueous solution may be at least one selected from the group consisting of water, alcohol, an aldehyde, ether, an ester and glycerol.

The organic acid may be formic acid or acetic acid.

The reduction firing may be executed at a temperature of 200° C. or lower.

The substrate may be any one selected from the group consisting of glass, polyimide, a polyethylene terephthalate (PET) film, a polyethylene naphthalate (PEN) film, polycarbonate and a thin film transistor (TFT).

According to another aspect of the present invention, there is provided a thin metal film electrode, fabricated by: applying a metal paste including a metal powder, an organic binder and an organic solvent to a substrate to form a thin metal film; and subjecting the thin metal film to reduction firing in an atmosphere containing an organic acid and an aqueous solution in a ratio ranging from 10:90 to 90:10.

The metal powder may be at least one selected from the group consisting of Cu, Ag, Au, Pt, Pd, Ni, Ta, In, Sn, Zn, Cr, Fe and Co.

The metal powder may contain nano-sized Cu powder particles.

The metal paste may be a copper paste including copper powder and a content of the copper powder may range from 10 to 90 parts by weight in relation to 100 parts by weight of the copper paste.

The substrate may be any one selected from the group consisting of glass, polyimide, a polyethylene terephthalate (PET) film, a polyethylene naphthalate (PEN) film, polycarbonate and a thin film transistor (TFT).

A ratio of areas of the thin metal film electrode before and after the reduction firing may range from 1:0.9 to 1:1.

After the reduction firing, a resistivity of the thin metal film electrode may be 20 mΩ·m² or less.

After the reduction firing, a resistivity of the thin metal film electrode may be 10 mΩ·m² or less.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a flowchart illustrating a process of fabricating a thin metal film electrode according to an exemplary embodiment of the present invention; and

FIG. 2 is a graph showing resistivity of a thin metal film electrode fabricated according to an exemplary embodiment of the present invention, depending on the content of an aqueous solution.

### DETAILED DESCRIPTION OF THE EXEMPLARY EMBODIMENT

Exemplary embodiments of the present invention will be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art.

Moreover, detailed descriptions related to well-known functions or configurations will be ruled out in order not to unnecessarily obscure subject matters of the present invention.

In addition, unless explicitly described to the contrary, the word “comprise” and variations such as “comprises” or “comprising,” will be understood to imply the inclusion of stated elements but not the exclusion of any other elements.

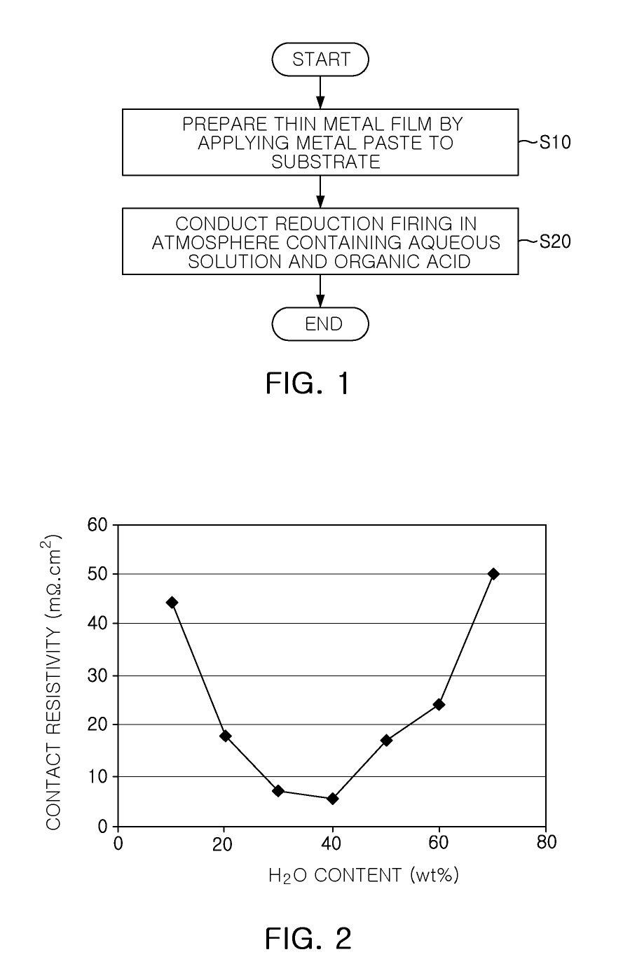

FIG. 1 is a flowchart illustrating a process of fabricating a thin metal film electrode according to an exemplary embodiment of the present invention, and FIG. 2 is a graph showing resistivities of a thin metal film electrode formed according to an exemplary embodiment of the present invention, depending on the contents of an aqueous solution.

Hereinafter, with reference to FIGS. 1 and 2, a method of fabricating a thin metal film electrode according to an exemplary embodiment of the present invention, as well as a thin metal film electrode fabricated by the same, will be described in detail.

Referring to FIG. 1, a method of fabricating a thin metal film electrode according to an exemplary embodiment includes: preparing a thin metal film by applying a metal paste including a metal powder and a dispersant to a substrate in operation S10 and subjecting the prepared thin metal film to reduction firing in an atmosphere containing an organic acid and an aqueous solution in a ratio ranging from 10:90 to 90:10 in operation S20.

In order to fabricate the thin metal film electrode, a metal paste including a metal powder, an organic binder and an organic solvent is applied to a substrate, thereby forming a thin metal film (operation S10).

The metal powder is used to provide electrical conductivity and may have low resistivity. Without particular limitation, the metal powder may be formed by using, for example, at least one selected from the group consisting of Cu, Ag, Au, Pt, Pd, Ni, Ta, In, Sn, Zn, Cr, Fe and Co.

According to an exemplary embodiment of the present invention, the metal powder may include copper particles and, in the case of using the copper particles, production costs may be decreased since Cu is relatively cheap as compared to other metals.

According to an exemplary embodiment of the present invention, nano-sized metal powder particles may be used. Using the nano-sized metal powder particles may reduce a firing temperature of the particles. The metal paste including the nano-sized metal powder particles may be fired at a low temperature.

According to an exemplary embodiment of the present invention, the metal powder may be included in an amount of 10 to 90 parts by weight in relation to 100 parts by weight of the metal paste. Specifically, the metal paste may be a copper paste and the copper paste may contain 10 to 90 parts by weight of copper powder in relation to 100 parts by weight of the copper paste.

If a content of the metal powder is less than 10 parts by weight, a metal density of a thin metal film electrode is decreased to cause an increase in a resistivity thereof. When the content exceeds 90 parts by weight, secondary agglomeration may occur between the metal powders contained in the metal paste, thus causing sedimentation of metal particles.

According to an exemplary embodiment of the present invention, since the content of the metal powder contained in the metal paste may be increased, it is possible to fabricate a thin metal film having a high metal density even without increasing the number of required coatings or film formation processes during low temperature firing.

The organic binder is used to improve a dispersibility of metal powder particles contained in the metal paste and, without being particularly limited, may include ethyl cellulose or the like.

The organic solvent is a dispensing solvent used to disperse the metal paste therein and, without being particularly limited, may include terpineol or the like.

The substrate is a material, to which a metal powder is applied, dried and fired to form a film, which may be fabricated by using glass, polyimide, a polyethylene terephthalate (PET) film, a polyethylene naphthalate (PEN) film, polycarbonate, or the like. Also, a base board such as a thin film transistor (TFT) may be employed.

According to an exemplary embodiment of the present invention, a thin metal film may be formed by applying a metal paste including a metal powder, an organic binder and an organic solvent to a substrate.

Then, after forming the thin metal film, the thin metal film is subjected to reduction firing in an atmosphere containing an organic acid and an aqueous solution.

The metal powder has a feature of being easily oxidized through exposure to oxygen during heat treatment at a high temperature. Specifically, copper (Cu) has relatively high reactivity and, when coming into contact with oxygen, is easily oxidized. Therefore, instead of Cu, noble metals having low reactivity such as Au, Pt, or the like, have often been used.

According to the exemplary embodiment of the present invention, in order to prevent oxidation of the metal powder, the firing is executed in an atmosphere containing an organic acid and an aqueous solution.

That is, a conventional firing method has been executed in a nitrogen atmosphere to reduce the reactivity of a metal powder; however, this method has a problem in that firing may proceed while the oxidized metal powder is not yet reduced during production of a metal paste.

Therefore, according to an exemplary embodiment of the present invention, in order to prevent oxidation of a metal powder and execute reduction of the oxidized metal powder, firing may be conducted in a reducing atmosphere.

According to an exemplary embodiment of the present invention, reduction firing of a metal paste is conducted in an atmosphere containing an organic acid and an aqueous solution to remove an organic material adhered around the metal powder and lead the reduction reaction to be suitably executed.

During reduction firing of the metal powder, if hydrogen or an organic acid is present, the reduction firing of the metal powder is successfully performed. However, the hydrogen or the organic acid may etch a surface of a thin metal film electrode to thereby cause a decrease in a surface resistivity and damage to the shape of the electrode, which in turn excessively decomposes an internal organic material and decreases the adhesiveness of the electrode to the substrate.

However, according to an exemplary embodiment of the present invention, since a metal paste may be subjected to reduction firing in an atmosphere containing an organic acid and an aqueous solution and, especially, containing a proper amount of aqueous solution, a surface of a thin metal film electrode may not be etched, even during reduction firing.

Therefore, according to an exemplary embodiment of the present invention, surface resistance as well as the original shape of the electrode may be maintained, and a thin metal film electrode may be fabricated while maintaining adhesiveness to a substrate.

The aqueous solution is used to prevent a thin metal film from being etched in a reducing atmosphere and, without being particularly limited, may include at least one selected from the group consisting of water, alcohol, an aldehyde, ether, an ester and glycerol.

The organic acid may remove an organic material adhered around the metal powder particle contained in the thin metal film and lead to a suitable reduction reaction of the metal powder oxidized during the preparation of a metal paste.

Without particular limitation, the organic acid may be formic acid or acetic acid.

In particular, according to an exemplary embodiment of the present invention, the thin metal film may be formed by reduction firing in an atmosphere containing an organic acid and an aqueous solution in a ratio ranging from 10:90 to 90:10.

If a content of the aqueous solution exceeds 90 wt %, a content of the organic acid is relatively decreased to inhibit reduction firing of the thin metal film. If the content of the aqueous solution is less than 10 wt %, etching of the thin metal film occurs, thus deteriorating the adhesiveness of a substrate.

According to a preferred embodiment of the present invention, the thin metal film may be subjected to reduction firing in an atmosphere containing an organic acid and an aqueous solution in a ratio ranging from 50:50 to 80:20.

If a content of the aqueous solution ranges from 20 to 50 wt %, reduction of the thin metal film may be optimized to thereby prevent the thin metal film from being over-etched, thereby preventing deformation of the shape of the thin metal film, while maintaining low resistivity.

According to an exemplary embodiment of the present invention, when the content of the aqueous solution ranges from 20 to 50 wt %, a resistivity of the same may be 20 mΩ·m² or less, to thereby attain a ratio of areas of a thin metal film electrode before and after reduction firing, ranging from 1:0.9 to 1:1.

More preferably, the thin metal film may be subjected to reduction firing in an atmosphere containing an organic acid and an aqueous solution in a ratio ranging from 60:40 to 70:30.

When a content of the aqueous solution ranges from 30 to 40 wt %, the reduction of the thin metal film may be maximized to thereby minimize a resistivity of a thin metal film electrode.

According to an exemplary embodiment of the present invention, if the content of the aqueous solution ranges from 30 to 40 wt %, a resistivity of the same may be 10 mΩ·m² or less to thereby attain a ratio of areas of a thin metal film electrode before and after reduction firing, of 1:1.

When the content of the aqueous solution is optimized, the metal powder contained in a thin metal film electrode may be thoroughly reduced without damage to an area of the thin metal film electrode, thereby decreasing a resistivity of the electrode.

According to an exemplary embodiment of the present invention, when a thin metal film is fired in an atmosphere containing an aqueous solution and an organic acid, the firing may be conducted at a low temperature.

Since a reducing atmosphere is prepared by adding an organic acid thereto, a decomposition temperature of an organic material in the reducing atmosphere may be lower than a decomposition temperature under air.

According to an exemplary embodiment of the present invention, since nano-sized metal powder particles are included, firing may be conducted at a low temperature.

As a particle size of a metal powder contained in a metal paste is decreased, a firing temperature thereof may also be reduced. For the metal paste containing small particles, compactness between particles may be given, thereby enabling firing even at a low temperature. For instance, a particle diameter of the metal powder may range from 1 nm to 1,000 nm.

Therefore, according to an exemplary embodiment of the present invention, since the metal paste contains the nano-sized metal powder particles, firing may be executed at a low temperature of 200° C. or less, even when the metal paste has a high metal density.

The firing temperature may vary and be suitably selected depending on a type of substrate employed; however, according to an exemplary embodiment of the present invention, a reduction firing temperature of the above thin metal film may be 200° C. or less.

If the reduction firing temperature exceeds 200° C., a substrate and a thin metal film may be excessively fired to oxidize the thin metal film or apply thermal stress to the substrate.

By a method of fabricating a thin metal film electrode according to an exemplary embodiment of the present invention, a thin metal film electrode having low resistivity may be formed even at 200° C. or less and, as a result, a thin metal film electrode having high reliability, capable of maintaining low resistivity while minimizing thermal stress to an electronic element may be formed.

Hereinafter, the following description will be given to explain a thin metal film electrode according to an exemplary embodiment of the present invention.

A thin metal film electrode according to an exemplary embodiment of the present invention may include a thin metal film containing a metal powder, applied in a metal paste form to a substrate. The thin metal film is characterized in that it is formed by reduction firing in an atmosphere containing an organic acid and an aqueous solution in a ratio ranging from 10:90 to 90:10.

The substrate is a material to which a metal powder is applied, dried and fired to form a film and may be formed by using glass, polyimide, a polyethylene terephthalate (PET) film, a polyethylene naphthalate (PEN) film, polycarbonate, or the like. Alternatively, a base board such as a thin film transistor (TFT) may be employed.

The metal powder is used to afford electrical conductivity and preferably has low resistivity. Without particular limitation, the metal powder may be at least one selected from the group consisting of Cu, Ag, Au, Pt, Pd, Ni, Ta, In, Sn, Zn, Cr, Fe and Co. Specifically, if copper powder is used, as in conventional methods, the powder may be easily oxidized due to excess reactivity of the copper powder and cannot be used.

However, according to an exemplary embodiment of the present invention, copper powder even having highly oxidative activity may be reduced through optimum reduction firing, thereby producing a thin metal film electrode having low resistivity.

In addition, since a low priced copper powder is used as the metal powder, production costs may be decreased.

According to an exemplary embodiment of the present invention, nano-sized metal powder particles may be used. More particularly, using nano-sized metal powder particles may reduce a firing temperature of the powder. For example, a particle diameter of the metal powder may range from 1 to 1,000 nm.

A metal paste containing the nano-sized metal powder may be subjected to low temperature firing.

According to an exemplary embodiment of the present invention, the metal powder is copper powder and the copper powder may be contained in an amount of 10 to 90 parts by weight in relation to 100 parts by weight of a copper paste.

If a content of the copper powder is less than 10 parts by weight, a metal density of a thin metal film electrode is reduced to increase a resistivity of the same. When the content exceeds 90 parts by weight, secondary agglomeration may occur between the metal powders contained in the copper paste, thus causing sedimentation of metal particles.

According to an exemplary embodiment of the present invention, a content of the metal powder contained in the metal paste may be increased, which in turn increases a metal density inside a thin metal film electrode, thereby enabling fabrication of a thin metal film electrode having low resistivity.

The foregoing metal powder is prepared in a metal paste form and, without particular limitation, may be applied to the substrate as described above through printing such as inkjet printing, thus forming a thin metal film.

The thin metal film may be formed by reduction firing in an atmosphere containing an organic acid and an aqueous solution in a ratio ranging from 10:90 to 90:10.

The thin metal film may be formed by reduction firing in an atmosphere containing an organic acid and an aqueous solution.

The organic acid is used to remove an organic material adhered around the metal powder contained in the thin metal film and lead to a suitable reduction of the metal powder oxidized during the preparation of the metal paste.

According to an exemplary embodiment of the present invention, since the thin metal film is fired in an atmosphere containing an organic acid, the metal powder oxidized during the preparation of the metal paste may be reduced during firing, thereby enabling production of a thin metal film electrode having low resistivity.

The organic acid used herein is not particularly limited, but may include formic acid or acetic acid.

The aqueous solution is used to prevent etching of a thin metal film in a reducing atmosphere and, according to an exemplary embodiment of the present invention, since firing is conducted in an atmosphere containing an aqueous solution, damage or deformation of an external shape of the thin metal film due to over-etching, may be prevented.

Especially, when firing is executed in an atmosphere containing an organic acid alone, there is a problem in that the thin metal film may be over-etched, thus causing deterioration in the adhesiveness of the thin metal film to a substrate.

However, according to an exemplary embodiment of the present invention, since firing is conducted in an atmosphere containing an organic acid and an aqueous solution, over-etching of the thin metal film may be prevented, thereby substantially maintaining the same area or a shape of the thin metal film before and after firing, without change.

According to an exemplary embodiment of the present invention, a thin metal film electrode having advantages in that the face resistance of an electrode, the shape of the electrode and the adhesiveness of the electrode to a substrate are continuously maintained.

Without particular limitation, the foregoing aqueous solution may be at least one selected from the group consisting of water, alcohol, an aldehyde, ether, an ester and glycerol.

Specifically, according to an exemplary embodiment of the present invention, the thin metal film may be subjected to reduction firing in an atmosphere containing an organic acid and an aqueous solution in a ratio ranging from 10:90 to 90:10.

If a content of the aqueous solution exceeds 90 wt %, a content of the organic acid is relatively decreased to inhibit reduction firing of the thin metal film. When the content of the aqueous solution is less than 10 wt %, etching of the thin metal film occurs, thus deteriorating adhesiveness to the substrate.

According to a preferred embodiment of the present invention, the thin metal film may be subjected to reduction firing in an atmosphere containing an organic acid and an aqueous solution in a ratio ranging from 50:50 to 80:20.

If a content of the aqueous solution ranges from 20 to 50 wt %, reduction of the thin metal film may be optimized to thereby prevent the thin metal film from being over-etched, in turn, prevent shape deformation of the thin metal film, while maintaining low resistivity.

In particular, when the content of the aqueous solution ranges from 20 to 50 wt %, a resistivity of the same may be 20 mΩ·m² or less, to thereby attain a ratio of areas of a thin metal film electrode before and after reduction firing, ranging from 1:0.9 to 1:1.

More preferably, the thin metal film may be subjected to reduction firing in an atmosphere containing an organic acid and an aqueous solution in a ratio ranging from 60:40 to 70:30.

When a content of the aqueous solution ranges from 30 to 40 wt %, reduction of the thin metal film may be maximized to thereby minimize a resistivity of a thin metal film electrode.

Accordingly, if the content of the aqueous solution ranges from 30 to 40 wt %, a resistivity of the same may be 10 mΩ·m² or less to thereby attain a ratio of areas of a thin metal film electrode before and after reduction firing, of 1:1.

In the case in which the content of the aqueous solution is optimized, a resistivity of a thin metal film electrode may be decreased by completely reducing the metal powder contained in the thin metal film electrode without damage to an area of the thin metal film electrode.

Hereinafter, the present invention will be described in detail with reference to the following inventive example and comparative example, however, the scope of the present invention should not be construed as being limited thereto.

### Example 1

The following Table 1 shows whether a thin metal film electrode was reduced and the electrode was deformed depending on the contents of an aqueous solution and an organic acid, according to an exemplary embodiment of the present invention.

After preparing a copper paste containing nano-sized copper powder particles, a thin metal film electrode was subjected to reduction firing depending on the contents of the aqueous solution and the organic acid.

TABLE 1

| Content of | Content of | | Ratio of Areas of Thin Metal |
|---|---|---|---|
| Aqueous | Organic | Reduction | Film Electrode Before and |
| Solution | Acid | or Not | After Reduction Firing |
| 100 | 0 | x | 1:1 |
| 90 | 10 | ∘ | 1:1 |
| 80 | 20 | ∘ | 1:1 |
| 70 | 30 | ∘ | 1:1 |
| 60 | 40 | ∘ | 1:1 |
| 50 | 50 | ∘ | 1:1 |
| 40 | 60 | ∘ | 1:1 |
| 30 | 70 | ∘ | 1:1 |
| 20 | 80 | ∘ | 1:0.9 |
| 10 | 90 | ∘ | 1:0.8 |
| 0 | 100 | ∘ | 1:0.2 |

Referring to the above table, in the case in which the content of the aqueous solution was 100 wt % and the organic acid was not included, reduction firing was not carried out because of the lack of the organic acid. As a result, the thin copper film electrode was fired in an oxidized state, thus showing a dark color.

When the content of the organic acid was 100 wt % and the aqueous solution was not included, over-etching occurred because of lack of the aqueous solution. As a result, it was found that an area of the thin copper film electrode was decreased after firing, compared to the area thereof before firing.

That is, when the organic acid was included alone, it can be seen that an external shape of the thin copper film electrode was deformed and adhesiveness thereof to a substrate was deteriorated.

On the other hand, in the case in which the thin metal film was subjected to reduction firing in an atmosphere containing the organic acid and the aqueous solution in a ratio ranging from 10:90 to 90:10, reduction firing of a thin copper film electrode was conducted owing to the organic acid, while over-etching during reduction firing was prevented by adding the aqueous solution to the atmosphere.

As a result, it was found that the thin copper film electrode after reduction firing showed a bright color and there was substantially no change in the area of the thin copper film electrode before and after the firing.

FIG. 2 is a graph showing a resistivity of the thin metal film electrode depending on the contents of the aqueous solution and the organic acid according to an exemplary embodiment of the present invention.

According to an exemplary embodiment of the present invention, it was found that a resistivity of the thin metal film electrode was 20 mΩ·m² or less, when the thin metal film was subjected to reduction firing in an atmosphere containing the organic acid and the aqueous solution in a ratio ranging from 50:50 to 80:20.

Further, referring to FIG. 2 and the foregoing table, it can be seen that the area of the thin metal film electrode was substantially similar before and after reduction firing when the content of the aqueous solution ranged from 20 to 50 wt %, and a ratio of the areas of the thin metal film electrode before and after reduction firing ranged from 1:0.9 to 1:1.

Moreover, in the case in which the thin metal film was subjected to reduction firing in an atmosphere containing an organic acid and an aqueous solution in a ratio ranging from 60:40 to 70:30 according to an exemplary embodiment of the present invention, it was found that a resistivity of a thin metal film electrode was 10 mΩ·m² or less.

Specifically, it can be seen that, when 70 wt % of the organic acid and 30 wt % of the aqueous solution were included, the resistivity was 7 mΩ·m² and, when 60 wt % of the organic acid and 40 wt % of the aqueous solution were included, the resistivity of the thin metal film electrode was at least 5.6 mΩ·m².

In addition, referring to FIG. 2 and the foregoing table, it can be seen that the area of the thin metal film electrode is substantially identical before and after reduction firing when the content of the aqueous solution ranges from 20 to 50 wt %, and a ratio of the areas of the thin metal film electrode before and after reduction firing was 1:1.

According to an exemplary embodiment of the present invention, since reduction firing is executed in an atmosphere containing an organic acid and an aqueous solution, a thin metal film electrode having low resistivity attained by reducing a metal powder while maintaining an original shape of the electrode may be fabricated.

Specifically, a thin metal film electrode having low resistivity may be formed through a reduction firing process by using a relatively low-priced metal having high reactivity such as copper, thereby reducing production costs.

Moreover, since the adhesiveness of a thin metal film electrode to a substrate is improved and deformation of an external shape of the thin metal film electrode is prevented, highly reliable wiring or other electronic elements having the thin metal film electrode according to the present invention may be manufactured.

As set forth above, according to an exemplary embodiment of the present invention, a thin metal film electrode having low resistivity may be manufactured through a low temperature firing process.

Specifically, a thin metal film electrode having low resistivity may be prepared by firing a low-priced copper paste at a low temperature, to thereby provide an electronic element having high reliability while reducing production costs.

While the present invention has been shown and described in connection with the exemplary embodiments, it will be apparent to those skilled in the art that modifications and variations can be made without departing from the spirit and scope of the invention as defined by the appended claims.

What is claimed is:

1. A method of fabricating a thin metal film electrode, the method comprising:
applying a metal paste including a metal powder, an organic binder and an organic solvent to a substrate to form a thin metal film; and
subjecting the thin metal film to reduction firing in an atmosphere containing an organic acid and an aqueous solution in a ratio ranging from 10:90 to 90:10.

2. The method of claim 1, wherein the metal powder is at least one selected from the group consisting of copper (Cu), silver (Ag), gold (Au), platinum (Pt), palladium (Pd), nickel (Ni), tantalum (Ta), indium (In), tin (Sn), zinc (Zn), chromium (Cr), iron (Fe) and cobalt (Co).

3. The method of claim 1, wherein the metal powder contains nano-sized copper powder particles.

4. The method of claim 1, wherein the metal paste is a copper paste containing copper powder, and a content of the copper powder ranges from 10 to 90 parts by weight in relation to 100 parts by weight of the copper paste.

5. The method of claim 1, wherein the thin metal film is subjected to reduction firing in an atmosphere containing an organic acid and an aqueous solution in a ratio ranging from 50:50 to 80:20.

6. The method of claim 1, wherein the thin metal film is subjected to reduction firing in an atmosphere containing an organic acid and an aqueous solution in a ratio ranging from 60:40 to 70:30.

7. The method of claim 1, wherein the aqueous solution is at least one selected from the group consisting of water, alcohol, an aldehyde, ether, an ester and glycerol.

8. The method of claim 1, wherein the organic acid is formic acid or acetic acid.

9. The method of claim 1, wherein the reduction firing is executed at a temperature of 200° C. or less.

10. The method of claim 1, wherein the substrate is any one selected from the group consisting of glass, polyimide, a polyethylene terephthalate (PET) film, a polyethylene naphthalate (PEN) film, polycarbonate and a thin film transistor (TFT).

11. A thin metal film electrode fabricated by:
applying a metal paste including a metal powder, an organic binder and an organic solvent to a substrate to form a thin metal film; and
subjecting the thin metal film to reduction firing in an atmosphere containing an organic acid and aqueous solution in a ratio ranging from 10:90 to 90:10.

12. The thin metal film electrode of claim 11, wherein the metal powder is at least one selected from the group consisting of copper (Cu), silver (Ag), gold (Au), platinum (Pt), palladium (Pd), nickel (Ni), tantalum (Ta), indium (In), tin (Sn), zinc (Zn), chromium (Cr), iron (Fe) and cobalt (Co).

13. The thin metal film electrode of claim 11, wherein the metal powder contains nano-sized copper powder particles.

14. The thin metal film electrode of claim 11, wherein the metal paste is a copper paste containing copper powder, and a content of the copper powder ranges from 10 to 90 parts by weight in relation to 100 parts by weight of the copper paste.

15. The thin metal film electrode of claim 11, wherein the substrate is any one selected from the group consisting of glass, polyimide, a polyethylene terephthalate (PET) film, a polyethylene naphthalate (PEN) film, polycarbonate and a thin film transistor (TFT).

16. The thin metal film electrode of claim 11, wherein a ratio of an area of the thin metal film electrode after the reduction firing to the area of the thin metal film electrode before the reduction firing ranges from 1:0.9 to 1:1.

17. The thin metal film of claim 11, wherein a resistivity of the thin metal film electrode after the reduction firing is 20 mΩ·m² or less.

18. The thin metal film of claim 11, wherein a resistivity of the thin metal film electrode after the reduction firing is 10 mΩ·m² or less.
